(19) United States
(12) Patent Application Publication
(10) Pub. No.: US 2023/0299130 A1
(43) Pub. Date: Sep. 21, 2023

(54) SEMICONDUCTOR DEVICE AND METHOD OF MANUFACTURING THE SAME

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Shunsuke ASABA, Himeji Hyogo (JP); Takuma SUZUKI, Himeji Hyogo (JP)

(21) Appl. No.: 17/890,041

(22) Filed: Aug. 17, 2022

(30) Foreign Application Priority Data
Mar. 18, 2022 (JP) 2022-043924

(51) Int. Cl. H01L 29/06; H01L 29/04; H01L 29/16; H01L 29/10; H01L 29/78; H01L 21/04; H01L 29/66

(52) U.S. Cl. CPC H01L 29/063; H01L 29/045; H01L 29/1608; H01L 29/1095; H01L 29/7813; H01L 21/0465; H01L 21/047; H01L 29/66068

(57) ABSTRACT

A semiconductor device includes a semiconductor part including a first semiconductor layer of a first conductivity type and a second semiconductor layer of a second conductivity type. The second semiconductor layer is provided in the first semiconductor layer. The semiconductor part includes first and second interfaces of the first semiconductor layer and the second semiconductor layer. The first interface intersects the second interface. The second semiconductor layer includes a plurality of sub-layers stacked in a direction orthogonal to the first interface. The second interface includes interfaces of the sub-layers of the second semiconductor layer and the first semiconductor layer. The second interface extending in a second direction inclined with respect to a first direction orthogonal to the first interface.

### CROSS-REFERENCE TO RELATED APPLICATIONS

This application is based upon and claims the benefit of priority from Japanese Patent Application No. 2022-043924, filed on Mar. 18, 2022; the entire contents of which are incorporated herein by reference.

### FIELD

Embodiments relate to a semiconductor device and a method of manufacturing the same.

### BACKGROUND

A semiconductor device used for power control or the like is required to reduce a leakage current and improve a breakdown voltage.

### BRIEF DESCRIPTION OF THE DRAWINGS

FIGS. 1A to 1C are schematic cross-sectional views showing a method of manufacturing a semiconductor device according to an embodiment;

FIGS. 2A and 2B are schematic views showing the method of manufacturing the semiconductor device according to the embodiment;

FIG. 3 is a schematic view showing a structure of the semiconductor device according to the embodiment;

FIGS. 4A and 4B are schematic cross-sectional views showing the structure of the semiconductor device according to the embodiment;

FIGS. 5A to 5C are schematic views showing a semiconductor device according to the embodiment; and

FIG. 6 is a schematic cross-sectional view showing the semiconductor device according to the embodiment.

### DETAlLED DESCRIPTION

According to one embodiment, a semiconductor device includes a semiconductor part including a first semiconductor layer of a first conductivity type and a second semiconductor layer of a second conductivity type. The second semiconductor layer is provided in the first semiconductor layer. The semiconductor part includes first and second interfaces of the first semiconductor layer and the second semiconductor layer. The first interface intersects the second interface. The second semiconductor layer includes a plurality of sub-layers stacked in a direction orthogonal to the first interface. The second interface includes interfaces of the sub-layers of the second semiconductor layer and the first semiconductor layer. The second interface extending in a second direction inclined with respect to a first direction orthogonal to the first interface.

Embodiments will now be described with reference to the drawings. The same portions inside the drawings are marked with the same numerals; a detailed description is omitted as appropriate; and the different portions are described. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

There are cases where the dispositions of the components are described using the directions of XYZ axes shown in the drawings. The X-axis, the Y-axis, and the Z-axis are orthogonal to each other. Hereinbelow, the directions of the X-axis, the Y-axis, and the Z-axis are described as an X-direction, a Y-direction, and a Z-direction. Also, there are cases where the Z-direction is described as upward and the direction opposite to the Z-direction is described as downward.

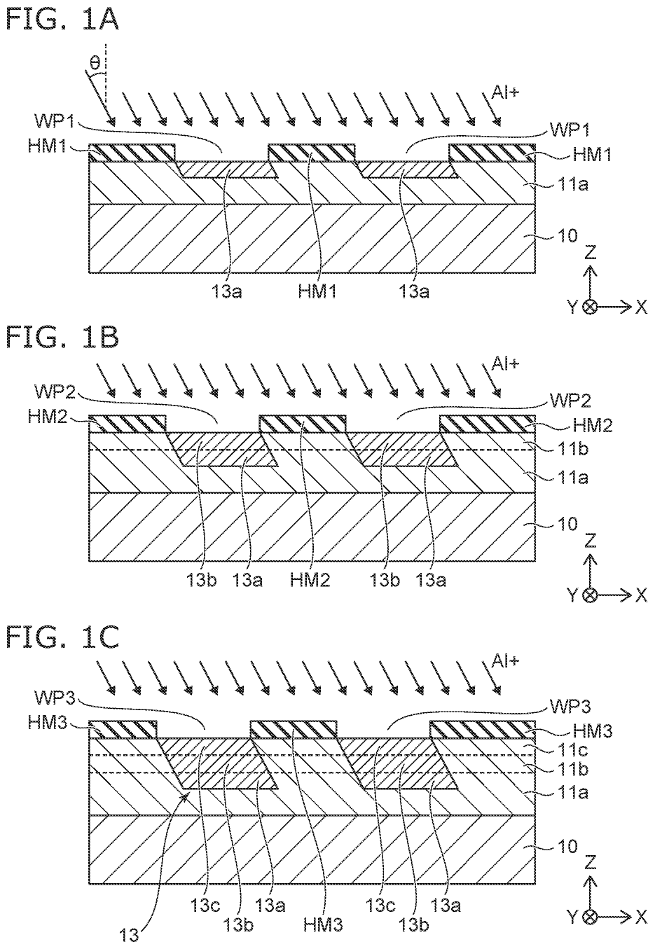

FIGS. 1A to 1C are schematic cross-sectional views showing a method of manufacturing a semiconductor device according to an embodiment. The semiconductor device is formed using, for example, a first semiconductor layer 11 of a first conductivity type. The first semiconductor layer 11 is, for example, epitaxially grown on a semiconductor substrate 10. The semiconductor substrate 10 is, for example, a silicon carbide (SiC) substrate or a silicon substrate. The first semiconductor layer 11 is, for example, a SiC layer having a hexagonal crystal structure. Hereinafter, the first conductivity type is described as an n-type, and a second conductivity type is described as a p-type.

As shown in FIG. 1A, a first semiconductor layer 11a is epitaxially grown on the semiconductor substrate 10. The first semiconductor layer 11a is formed using, for example, a chemical vapor deposition (CVD) method. The first semiconductor layer 11a is epitaxially grown on a Si plane of SiC which serves as a growth plane in a [0001] direction of the hexagonal crystal. The semiconductor substrate 10 has an upper surface provided with an off-angle of, for example, 4 degrees with respect to the Si plane.

Subsequently, an ion implantation mask HM1 is formed on the first semiconductor layer 11a, and a second-conductivity-type impurity such as aluminum (Al) is ion-implanted into the first semiconductor layer 11a through a first opening WP1 of the ion implantation mask HM1. Thereby, a second semiconductor layer 13a of the second conductivity type is formed in the first semiconductor layer 11a.

The second-conductivity-type impurity is implanted in a direction inclined with respect to an upper surface of the first semiconductor layer 11a. The implantation angle θ that is defined between an implantation direction and a direction perpendicular to the upper surface of the first semiconductor layer 11a is, for example, the same as the off-angle of the semiconductor substrate 10. Thereby, the second-conductivity-type impurity is ion-implanted in the [0001] direction, i.e., a direction perpendicular to a C-plane of the hexagonal crystal.

As shown in FIG. 1B, a first semiconductor layer 11b is formed on the first semiconductor layer 11a by an epitaxial growth. The first semiconductor layer 11b has, for example, the same composition as a composition of the first semiconductor layer 11a. The first semiconductor layer 11b includes a first-conductivity-type impurity with a concentration same as a concentration of a first-conductivity-type impurity in the first semiconductor layer 11a. Alternatively, the first semiconductor layer 11b may include a first-conductivity-type impurity with a different concentration from a concentration of the first-conductivity-type impurity in the first semiconductor layer 11a. The second-conductivity-type impurity ion-implanted into the first semiconductor layer 11a is activated by a heat treatment after the ion implantation or by temperature rising in the epitaxial growth process.

Subsequently, an ion implantation mask HM2 is formed on the first semiconductor layer 11b, and a second-conductivity-type impurity such as aluminum (Al) is ion-implanted into the first semiconductor layer 11b through a second opening WP2 of the ion implantation mask HM2. The second-conductivity-type impurity is ion-implanted into the first semiconductor layer 11b at the same implantation angle θ as the implantation angle θ when the second-conductivity-type impurity is implanted into the first semiconductor layer 11a. Thereby, a second semiconductor layer 13b of the second conductivity type is formed in the first semiconductor layer 11b.

The ion implantation mask HM2 includes the second opening WP2 having the same width as a width of the first opening WP1 in the ion implantation mask HM1. The second opening WP2 is provided at a horizontal position displaced in a reverse direction of the implantation direction (e.g., a reverse direction of the X-direction) with respect to the horizontal position of the first opening WP1. Here, the horizontal position is a relative position in a horizontal direction along upper surfaces of the first semiconductor layer 11a and the second semiconductor layer 11b.

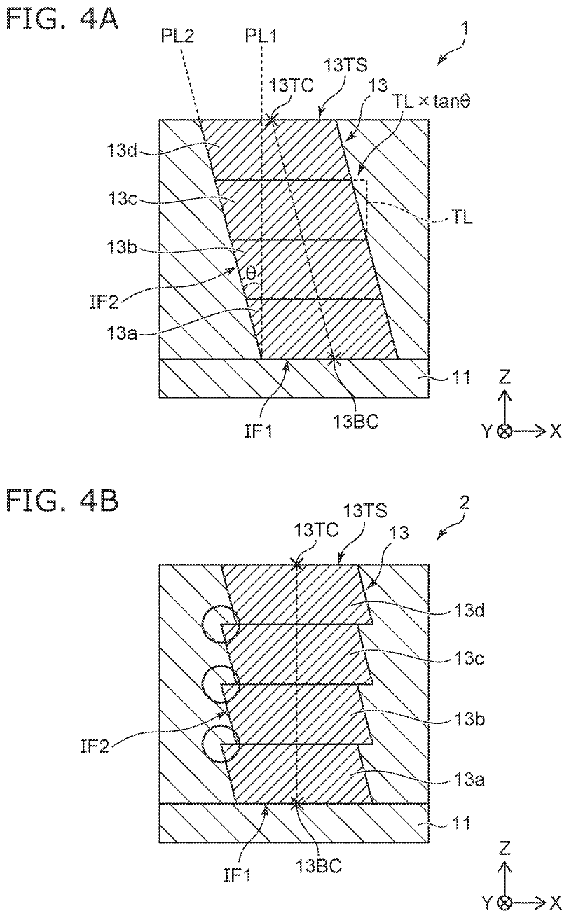

A displacement amount of the second opening WP2 in the horizontal direction with respect to the first opening WP1 is equal to, for example, a product of a layer thickness in the Z-direction of the first semiconductor layer 11b and a tangent of the implantation angle θ (see FIG. 4A). Thereby, the second semiconductor layer 13a and the second semiconductor layer 13b are formed such that the side surfaces thereof (i.e., the interface between the first semiconductor layer 11 and a second semiconductor layer 13) are continuously connected.

As shown in FIG. 1C, a first semiconductor layer 11c is formed on the first semiconductor layer 11b by an epitaxial growth. The first semiconductor layer 11c has, for example, the same composition as the composition of the first semiconductor layers 11a and 11b. The first semiconductor layer 11c includes a first-conductivity-type impurity with a concentration same as the concentration of the first-conductivity-type impurity in the first semiconductor layer 11b. Alternatively, the first semiconductor layer 11c may include a first-conductivity-type impurity with a concentration different from the concentration of the first-conductivity-type impurity in the first semiconductor layer 11b. The second-conductivity-type impurity that is ion-implanted into the first semiconductor layer 11b is activated by a heat treatment after the ion implantation or by temperature rising in the epitaxial growth process.

Subsequently, an ion implantation mask HM3 is formed on the first semiconductor layer 11c, and a second-conductivity-type impurity such as aluminum (Al) is ion-implanted into the first semiconductor layer 11c through a third opening WP3 of the ion implantation mask HM3. The second-conductivity-type impurity is ion-implanted into the first semiconductor layer 11c at the same implantation angle θ as the implantation angle θ when the second-conductivity-type impurities are implanted into the first semiconductor layers 11a and 11b. Thereby, a second semiconductor layer 13c of the second conductivity type is formed in the first semiconductor layer 11c.

The ion implantation mask HM3 includes the third opening WP3 having the same width as the width of the second opening WP2 in the ion implantation mask HM2. The third opening WP3 is provided at a horizontal position displaced in the reverse direction of the implantation direction (e.g., the reverse direction of the X-direction) with respect to the horizontal position of the second opening WP2. A displacement amount of the third opening WP3 in the horizontal direction with respect to the second opening WP2 is equal to, for example, a product of a layer thickness in the Z-direction of the first semiconductor layer 11c and the tangent of the implantation angle θ. Thereby, the second semiconductor layers 13b and 13c are formed such that the side surfaces thereof are continuously connected. The ion implantation masks HM1 to HM3 each are, for example, a hard mask such as a silicon oxide film or a metal film, or a resin such as a resist.

Hereinafter, a stacked body of the first semiconductor layers 11a to 11c is described as the first semiconductor layer 11. Also, a stacked body of the second semiconductor layers 13a to 13c is described as the second semiconductor layer 13. It should be noted that the embodiment is not limited to the manufacturing method described above. For example, each stacked body of the first semiconductor layer 11 and the second semiconductor layer 13 may include four or more layers.

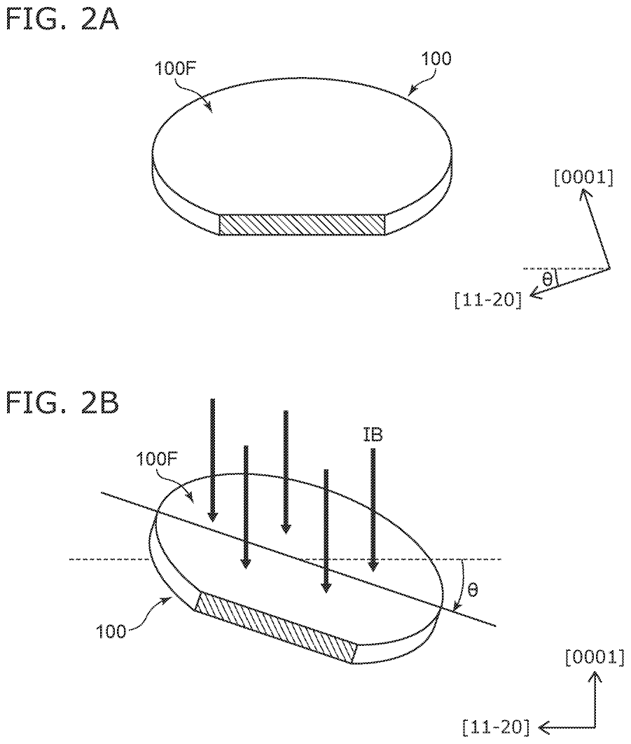

FIGS. 2A and 2B are schematic views showing the method of manufacturing the semiconductor device according to the embodiment. FIGS. 2A and 2B show a wafer 100 used for manufacturing the semiconductor device. The wafer 100 includes the semiconductor substrate 10 and the first semiconductor layer 11.

As shown in FIG. 2A, the wafer 100 has, for example, an orientation flat parallel to a (10-10) plane (hereinafter referred to as an M-plane) of a hexagonal crystal. Moreover, a front surface 100F of the wafer 100 has a predetermined off-angle θ with respect to a (0001) plane of the hexagonal crystal (hereinafter referred to as the C-plane).

As shown in FIG. 2B, when the second-conductivity-type impurity (Al) is ion-implanted, the wafer 100 is arranged such that the front surface 100F thereof is inclined with respect to an ion beam IB. The wafer 100 is set to be inclined clockwise in a plane including, for example, a [11-20] direction and the [0001] direction, i.e., in the M-plane. The wafer 100 is inclined by the implantation angle θ from a position orthogonal to the ion beam IB. When the front surface 100F is inclined clockwise in the M plane by, for example, 4 degrees from the C-plane, that is, when the off-angle θ is 4 degrees, the incident ion beam IB is perpendicular to the C-plane at the implantation angle θ of 4 degrees.

Moreover, the embodiment is not limited to the example. The incident ion beam IB may be perpendicular to a crystal plane inclined clockwise in the M-plane by, for example, 17 degrees from the C-plane. In such a crystal plane and the C-plane, an atomic spacing becomes relatively wide, and so-called a channeling ion implantation can take place. Therefore, the ion-implanted second-conductivity-type impurity can be more widely distributed in the depth direction (e.g., Z-direction). That is, in the manufacturing method according to the embodiment, the number of epitaxial growth steps to obtain the second semiconductor layer 13 having a predetermined thickness can be reduced.

When the off-angle θ of the wafer is, for example, 4 degrees and the front surface 100F is inclined clockwise in the M-plane by 21 degrees, the incident ion beam IB enters in a channeling direction. Moreover, when the off-angle θ of the wafer 100 is −4 degrees and the front surface 100F is inclined clockwise in the M-plane by 13 degrees, the incident ion beam IB enters in the channeling direction. Thereby, it is possible to reduce the mask shielding effect due to the thicknesses of the ion implantation masks HM1 to HM3.

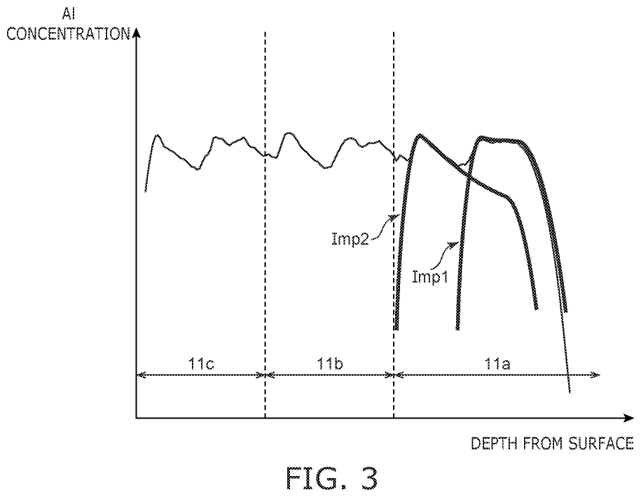

FIG. 3 is a schematic view showing a structure of the semiconductor device according to the embodiment. FIG. 3 is a schematic view illustrating a concentration profile of the second-conductivity-type impurity (Al) in the second semiconductor layer 13. A horizontal axis is a depth from a surface. A vertical axis is an Al concentration.

In the example, two step ion implantations are performed in each of the first semiconductor layers 11a to 11c. In each ion implantation, Al ions are implanted in a direction perpendicular to the C-plane. In FIG. 3, Imp1 represents a first Al distribution introduced into the first semiconductor layer 11a by the first ion implantation. Imp2 represents a second Al distribution introduced into the first semiconductor layer 11a by the second ion implantation. The total Al distribution in the first semiconductor layer 11a is a sum of the first Al distribution and the second Al distribution.

The first ion implantation is performed, for example, at room temperature under conditions of an implantation energy of 900 keV and an Al dose amount of 1×10¹³ cm⁻². The second ion implantation is performed, for example, at room temperature under conditions of an implantation energy of 200 keV and an Al dose amount of 6×10¹² cm⁻³. The embodiment is not limited to the example. For example, the high acceleration implantation may be performed at 600 to 1200 key, and the low acceleration implantation may be performed at 100 to 400 keV.

Also, in the first semiconductor layers 11b and 11c, the two step ion implantations are performed respectively under the above-described conditions. The Al distributions in the first semiconductor layers 11b and 11c each are the same distribution as the Al distribution introduced by the two step ion implantations. Moreover, the first semiconductor layers 11b and 11c each have a layer thickness (i.e., a thickness in the Z-direction) of, for example, 1.5 micrometers (μm).

As shown in FIG. 3, the first semiconductor layers 11a to 11c each have the Al distribution in which two concentration peaks appear corresponding to the two ion implantations. That is, the second semiconductor layers 13a to 13c formed in the first semiconductor layers 11a to 11c each include the second-conductivity-type impurity distribution with the concentration peaks corresponding to the number of ion implantations. In other words, each of the second semiconductor layers 13a to 13c is formed by at least one ion implantation, and each of the second-conductivity-type impurity distributions thereof includes at least one concentration peak.

FIGS. 4A and 4B are schematic cross-sectional views showing the structure of the semiconductor device according to the embodiment. FIG. 4A is a cross-sectional view showing the second semiconductor layer 13 of a semiconductor device 1 according to the embodiment. FIG. 4B is a cross-sectional view showing the second semiconductor layer 13 of a semiconductor device 2 according to a comparative example.

In the semiconductor device 1 shown in FIG. 4A, the second semiconductor layers 13a to 13d are stacked so that the horizontal positions thereof displaced from each other. For example, an impurity ion-implanted into the semiconductor layers of SiC is not diffused by the subsequent heat treatment. Therefore, the impurity distribution is maintained as ion-implanted in each semiconductor layer.

The displacement amounts in the horizontal direction of the second semiconductor layers 13a to 13d reflect a relationship of horizontal positions of the first to third openings WP1 to WP3 included in the ion implantation masks HM1 to HM3 (see FIGS. 1A to 1C). A displacement amount between two adjacent layers among the second semiconductor layers 13a to 13d is equal to, for example, a product of a layer thickness TL of each layer and a tangent of the implantation angle θ (i.e., tan θ).

As shown in FIG. 4A, a first interface IF1 and a second interface IF2 are provided between the first semiconductor layer 11 and the second semiconductor layer 13. The first interface IF1 is a boundary between the first semiconductor layer 11 and a bottom surface of the second semiconductor layer 13. The second interface IF2 intersects the first interface IF1.

The second interface IF2 extends along, for example, a second plane PL2 inclined with respect to a first plane PL1 that is orthogonal to the first interface IF1. In other words, in the X-Z plane, the second interface IF2 extends in a second direction inclined with respect to a first direction orthogonal to the first interface IF1. An inclination angle of the second plane PL2 with respect to the first plane PL1 is equal to the implantation angle θ of the second-conductivity-type impurity. Moreover, a straight line connecting the center point 13BC of the first interface IF1 and the center point 13TC of a front surface 13TS opposite to the first interface IF1 is parallel to the second plane PL2.

The second interface IF2 includes a direction along the first interface IF1. The second interface IF2 includes a direction, for example, orthogonal to the X-direction, i.e., the Y-direction. Moreover, the second interface IF2 includes a direction inclined by the implantation angle θ with respect to a direction orthogonal to the first interface IF1, i.e., the Z-direction.

In the semiconductor device 2 shown in FIG. 4B, the second semiconductor layer 13 is formed, for example, without relatively displacing the horizontal positions of the first to third openings WP1 to WP3 of the ion implantation masks HM1 to HM3. The second semiconductor layers 13b to 13d are provided directly above the second semiconductor layers 13a to 13c, respectively. Therefore, the straight line connecting the center point 13BC of the first interface IF1 and the center point 13TC of the front surface 13TS opposite to the first interface IF1 is orthogonal to the first interface IF1.

As shown in FIG. 4B by circles, the second interface IF2 includes a step at a boundary between adjacent two layers of the second semiconductor layers 13a to 13d. Such a step provides a non-uniform electric field or local electric field concentration between the first semiconductor layer 11 and the second semiconductor layer 13. Therefore, in the semiconductor device 2, a leakage current may increase or a breakdown voltage may decrease around the steps.

In contrast, in the semiconductor device 1 according to the embodiment, the second interface IF2 between the first semiconductor layer 11 and the second semiconductor layer 13 is flat and extends along the second plane PL2. Therefore, in the semiconductor device 1, it is possible to prevent the leakage current due to the steps in the second interface IF2 and to prevent the breakdown voltage from decreasing.

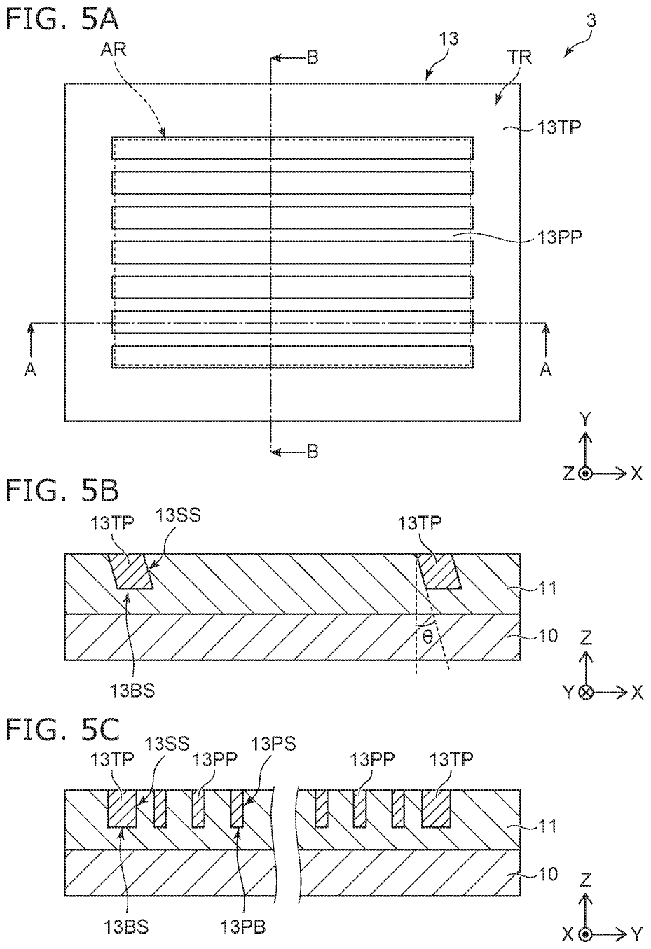

FIGS. 5A to 5C are schematic views showing a semiconductor device 3 according to the embodiment. FIGS. 5A to 5C are schematic views showing a super junction structure (Si structure) in the semiconductor device 3. FIG. 5A is a plan view showing the front surface 13TS of the second semiconductor layer 13. FIG. 5B is a cross-sectional view along A-A line shown in FIG. 5A. FIG. 5C is a cross-sectional view along B-B line shown in FIG. 5A.

As shown in FIG. 5A, the second semiconductor layer 13 includes an active region and a termination region TR. The termination region TR surrounds the active region AR. The second semiconductor layer 13 includes multiple pillar portions 13PP and a termination portion 13TP. The pillar portions 13PP are provided in the active region AR. The termination portion 13TP is provided in the termination region TR and surrounds the active region AR. Each of the multiple pillar portions 13PP is provided with a stripe shape extending in the X-direction. The multiple pillar portions 13PP are arranged in the Y-direction.

As shown in FIG. 5B, the termination portion 13TP of the second semiconductor layer 13 has a bottom surface 13BS and a side surface 13SS. The side surface 13SS is inclined with respect to a plane perpendicular to the bottom surface 13BS. Here, the X-Z plane is the M-plane of the hexagonal crystal. The inclination angle of the side surface 13SS is the same as the implantation angle θ of the ion implantation. In other words, the termination portion 13TP includes the first interface IF1 and the second interface IF2 (see FIG. 4A). The bottom surface 13BS of the termination portion 13TP is the first interface IF1. The side surfaces 13SS of the termination portion 13TP is the second interface IF2 that is provided in a direction along the bottom surface 13BS, e.g., the X-direction.

As shown in FIG. 5C, in the Y-Z plane, the side surface 13SS of the termination portion 13TP is orthogonal to the bottom surface 13BS of the termination portion 13TP. The pillar portion 13PP has a side surface 13PS orthogonal to a bottom surface 13PB thereof. Moreover, the side surface 13PS of the pillar portion 13PP is orthogonal to the side surface 13SS of the termination portion 13TP (see FIG. 5A).

In the semiconductor device 3, the steps (see FIG. 4B) in the inclined side surface 13SS of the second semiconductor layer 13 can be eliminated in the termination region TR in which the electric field concentration is likely to occur. Thereby, it is possible to prevent the leakage current from increasing and the breakdown voltage from being reduced.

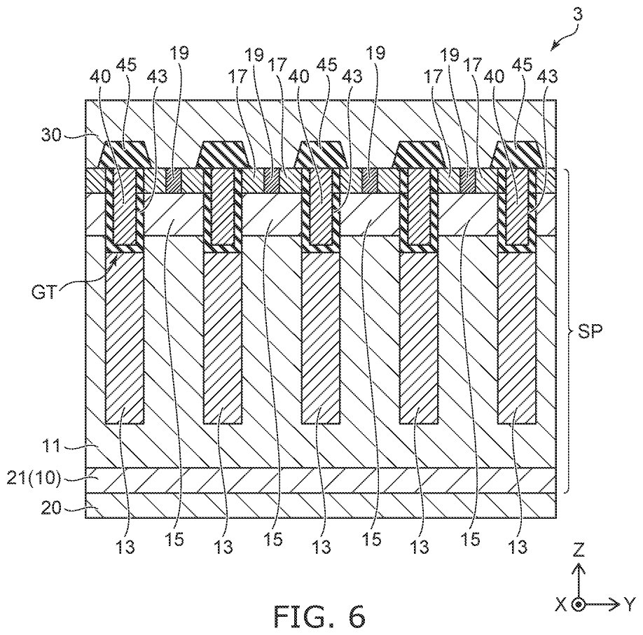

FIG. 6 is a schematic cross-sectional view showing the semiconductor device 3 according to the embodiment. FIG. 6 is a cross-sectional view of the active region AR along B-B line in FIG. 5A. The semiconductor device 3 is, for example, a MOS transistor.

As shown in FIG. 6, the semiconductor device 3 includes a semiconductor part SP, a first electrode 20, a second electrode 30, and a control electrode 40. The first electrode 20 is, for example, a drain electrode. The second electrode 30 is, for example, a source electrode. The control electrode 40 is, for example, a gate electrode.

The semiconductor part SP is provided between the first electrode 20 and the second electrode 30. The first electrode 20 is provided on a back surface of the semiconductor part SP. The second electrode 30 is provided on a front surface of the semiconductor part SP.

The control electrode 40 is provided inside a trench GT. The trench GT is provided on the front surface side of the semiconductor part SP. That is, the semiconductor device 3 has a trench gate structure. The control electrode 40 is provided between the first electrode 20 and the second electrode 30. The control electrode 40 is electrically insulated from the semiconductor part SP by a first insulating film 43. Also, the control electrode 40 is electrically insulated from the second electrode 30 by a second insulating film 45. The first insulating film 43 is, for example, a gate insulating film. The second insulating film 45 is, for example, an interlayer insulating film.

The semiconductor part SP includes the first semiconductor layer 11, the second semiconductor layer 13, a third semiconductor layer 15 of the second conductivity type, a fourth semiconductor layer 17 of the first conductivity type, a fifth semiconductor layer 19 of the second conductivity type, and a sixth semiconductor layer 21 of the first conductivity type.

The first semiconductor layer 11 extends between the first electrode 20 and the second electrode 30. Multiple second semiconductor layers 13 are provided in the first semiconductor layer 11 and are arranged in the Y-direction. The first semiconductor layer 11 and the second semiconductor layers 13 provide the so-called Si structure. In the example, the control electrode 40 is provided between each of the second semiconductor layers 13 and the second electrode 30.

The third semiconductor layer 15 is provided between the first semiconductor layer 11 and the second electrode 30. The third semiconductor layer 15 is provided between two adjacent control electrodes 40 and faces the control electrodes 40 via the first insulating film 43.

The fourth semiconductor layer 17 is partially provided on the third semiconductor layer 15 between the third semiconductor layer 15 and the second electrode 30. The fourth semiconductor layer 17 is in contact with the first insulating film 43.

The fifth semiconductor layer 19 is partially provided on the third semiconductor layer 15 between the third semiconductor layer 15 and the second electrode 30. The fourth semiconductor layer 17 and the fifth semiconductor layer 19 are arranged on the third semiconductor layer 15.

The second electrode 30 is connected to the fourth semiconductor layer 17 and the fifth semiconductor layer 19 at the front surface side of the semiconductor part SR The second electrode 30 contacts the fourth semiconductor layer 17 and the fifth semiconductor layer 19 with, for example, an ohmic connection.

The sixth semiconductor layer 21 is provided between the first semiconductor layer 11 and the first electrode 20. The sixth semiconductor layer 21 is formed by, for example, thinning the semiconductor substrate 10 to be a prescribed thickness. The semiconductor substrate 10 is thinned by, for example, grinding the back surface thereof. The first electrode 20 is connected to the sixth semiconductor layer 21 with, for example, an ohmic connection.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a semiconductor part including a first semiconductor layer of a first conductivity type and a second semiconductor layer of a second conductivity type, the second semiconductor layer being provided in the first semiconductor layer,
the semiconductor part including first and second interfaces of the first semiconductor layer and the second semiconductor layer, the first interface intersecting the second interface,
the second semiconductor layer including a plurality of sub-layers stacked in a direction orthogonal to the first interface,
the second interface including interfaces of the plurality of sub-layers of the second semiconductor layer and the first semiconductor layer,
the second interface extending in a second direction inclined with respect to a first direction orthogonal to the first interface.

2. The device according to claim 1, wherein
the second semiconductor layer has a concentration distribution in the first direction of a second-conductivity-type impurity, the concentration distribution including a concentration peak of the second-conductivity-type impurity in each sub-layer of the second semiconductor layer.

3. The device according to claim 1, wherein the second interface is a plane including the second direction and a third direction orthogonal to the first direction and the second direction.

4. The device according to claim 1, wherein
the semiconductor part is a hexagonal crystal structure,
the first direction and the second direction are included in an M-plane of the hexagonal crystal, and
an inclination angle of the second direction with respect to the first direction is equal to an inclination angle of the first interface with respect to a C-plane of the hexagonal crystal.

5. The device according to claim 1, wherein
the semiconductor part is a hexagonal crystal structure, the first direction and the second direction being included in an M-plane of the hexagonal crystal, and
an inclination angle of the second direction with respect to the first direction in the M-plane has a value obtained by adding 17 degrees to an inclination angle of the first interface with respect to a C-plane of the hexagonal crystal or by subtracting the inclination angle of the first interface from 17 degrees.

6. The device according to claim 4, wherein the second semiconductor layer includes a plurality of pillar portions and a termination portion,
the pillar portions each extending in a direction along the first interface, the pillar portions being arranged in a third direction orthogonal to the direction along the first interface and the second direction,
the termination portion surrounding the plurality of pillar portions.

7. The device according to claim 6, wherein the termination portion of the second semiconductor layer includes the second interface orthogonal to the direction along the first interface, and
the pillar portions of the second semiconductor layer each include another interface orthogonal to the first interface and the second interface.

8. The device according to claim 1, wherein the second direction is parallel to a direction directed from a center point of the first interface toward a center point of a front surface of the second semiconductor layer, the front surface being on a side opposite to the first interface.

9. A method of manufacturing a semiconductor device comprising:
forming a first mask on a front surface of a first semiconductor layer of a first conductivity type, the first mask including a first opening, the first semiconductor layer having a hexagonal crystal structure;
introducing a second-conductivity-type impurity into the first semiconductor layer using ion implantation through the first opening of the first mask, the second-conductivity-type impurity being ion-implanted in a channeling direction perpendicular to either a C-plane of the hexagonal crystal or a crystal plane inclined at 17 degrees with respect to the C-plane, the channeling direction being inclined with respect to the front surface of the first semiconductor layer;
forming a second first semiconductor layer on the first semiconductor layer;
forming a second mask on the second first semiconductor layer, the second mask having a second opening with a size same as a size of the first opening of the first mask, the second opening being displaced along a front surface of the second first semiconductor layer with respect to a position of the first opening of the first mask, the second opening being displaced in a direction opposite to a projected direction of the channeling direction on the front surface of the second first semiconductor layer; and
introducing another second-conductivity-type impurity into the second first semiconductor layer using ion implantation through the second opening of the second mask, said another second-conductivity-type impurity being ion-implanted in the channeling direction.

10. The method according to claim 9, wherein a displacement amount of the second opening with respect to the first opening is a product of a thickness of the second first semiconductor layer and a tangent of an inclination angle of the channeling direction, the thickness of the second first semiconductor layer being defined in a direction perpendicular to the front surface of the second first semiconductor layer, the inclination angle of the channeling direction being defined with respect to the direction perpendicular to the surface of the second first semiconductor layer.

11. The method according to claim 9, wherein the second-conductivity-type impurity is introduced respectively into the first semiconductor layer and the second first semiconductor layer by using a first ion implantation under a first acceleration energy and a second ion implantation under a second acceleration energy, the second acceleration energy being lower than the first acceleration energy.

12. The method according to claim 11, wherein the second ion implantation is performed after the first ion implantation.
